(19) United States
(12) Patent Application Publication
(10) Pub. No.: US 2006/0194370 A1
(43) Pub. Date: Aug. 31, 2006

(54) Radio frequency module and fabrication method thereof

(75) Inventors: Young Jin Lee, Yongin (KR); Doo Cheol Park, Suwon (KR); Seung Hee Lee, Suwon (KR); Sang Wook Park, Suwon (KR); Nam Hyeong Kim, Suwon (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 11/328,197

(22) Filed: Jan. 10, 2006

(30) Foreign Application Priority Data
Feb. 25, 2005 (KR) 10-2005-16000

(51) Int. Cl. H01L 21/50; H01L 23/02

(52) U.S. Cl. 438/118; 257/678

(57) ABSTRACT

The present invention relates to a RF module and a fabrication method thereof, wherein the packaging steps of a SAW component and a module is carried out simultaneously, thereby simplifying the fabrication process and reducing the size of the module. In the invention, a chip component is mounted on a substrate having component-connecting patterns thereon, and a SAW component in a bare chip is flip-bonded to the substrate. Thereafter, the SAW component is selectively laminated with a film and then molded; or the SAW component and the chip component are laminated as a whole and metal-plated, without any molding; or a metal wall is disposed between the substrate and the SAW component and then molded. As a result, this reduces the size of the RF modules, and simplifies the fabrication process, thereby benefiting from a cost-saving effect.

### CLAIM OF PRIORITY

The present application is based on, and claims priority from, Korean Application Number 2005-16000, filed Feb. 25, 2005, the disclosure of which is hereby incorporated by reference herein in its entirety.

### BACKGROUND OF THE INVENTION

1. Field of the Invention

The present invention relates to a Radio Frequency (RF) module containing at least one Surface Acoustic Wave (SAW) component, and more particularly, to an RF module and a fabrication method thereof, in which a SAW component in a bare chip is directly mounted on a substrate to reduce the size of a module.

2. Description of the Related Art

In the field of wireless communication terminals such as Local Area Network (LAN), mobile phone, PDA, etc., the current trend has been multi-function and compact size. Therefore, there have been attempts to reduce the size of the various components used in the wireless communication terminals.

The components containing SAW are widely used in filters, duplexers, etc. of the wireless communication terminals, and there have been attempts to utilize a module form, wherein a number of components come in a package to make the size more compact. The term, RF module will be used hereinafter to refer to the components containing SAW elements in a module form.

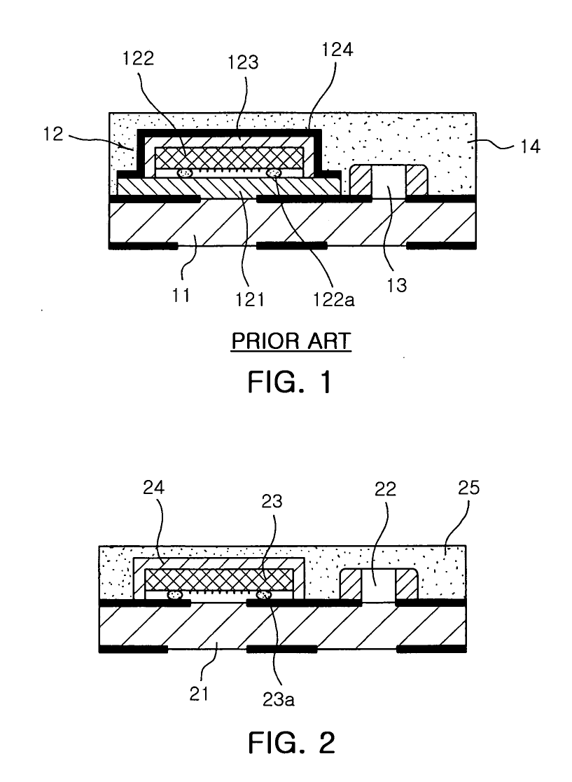

With reference to FIG. 1 in which the structure of an RF module of the prior art is shown, RF modules are previously manufactured by mounting a packaged SAW component 12 and a chip component 13 other than a SAW, and molding the entire top part of the substrate 11 with resin.

The SAW component 12 is formed by mounting a SAW chip 122 on the ceramic substrate 121, laminating a thermosetting film 123 on the top of the SAW chip, and plating the top of the thermosetting film 123 with metal 124, thereby sealing the saw chip 122. Other than the above method, the SAW chip can be sealed in the prior art by flip-bonding or wire-bonding the SAW chip to a cavity-shaped package where a metal cover comes on top by seam welding or heat fusion welding.

According to the above method of the prior art, since the packaged SAW component 12 and the chip component 13 are mounted on the substrate 11 and then molded, forming a module has a minimal effect in size reduction.

Currently, the demand for more compact size is on the rise in the field of the wireless communication terminal, and therefore, the RF modules need to be improved as they are essential in the wireless communication terminals.

### SUMMARY OF THE INVENTION

The present invention has been made to solve the foregoing problems of the prior art and it is therefore an object of the present invention to provide an RF module and a fabrication method thereof, which can accommodate size reduction and simplify the fabrication process by sealing the SAW component and packaging the RF module at the same time.

According to an aspect of the present invention for realizing the object, there is an RF module comprising: a substrate having component-connecting patterns formed thereon; at least one chip component other than a SAW element mounted on the substrate; at least one SAW component in a bare chip bonded to the substrate; and a package that seals the SAW component, and protects the connecting patterns and the chip components.

In addition, the package of the RF module according to the present invention may comprise: a thermosetting film laminated on the SAW component; molding resin coated on the connecting patterns, a chip component, and a SAW component laminated with the thermosetting film; or a thermosetting film that is laminated on the connecting patterns, the chip component, and the SAW component; a metal-plated layer formed on the top of the thermosetting film; or molding resin which is coated on the SAW component, the metal wall formed on the peripheral edge of the SAW component, the connecting patterns, the chip component, and the SAW component.

According to another aspect of the invention for realizing the object, there is a fabrication method of an RF module comprising steps of: Solder-bonding a plurality of chip components on the substrate having a plurality of connecting patterns formed repeatedly; flip-bonding at least one SAW component in a bare chip on the substrate; forming a package to protect the connecting patterns, mounted chip components and the SAW components; and dicing the packaged substrate to form a plurality of RF modules.

Furthermore, according to the fabrication method described above, the step of forming a package may comprise: punching the thermosetting film and laminating it on the SAW component and then molding with resin to cover the connecting patterns, the chip component, the laminated SAW component; laminating the connecting patterns, the chip component, and the SAW chip with the thermosetting film which is then removed partially in the boundaries among a plurality of modules and then metal-plating the top of the substrate and the thermosetting film; or forming a metal wall connected to the substrate on the peripheral edge of the SAW chip and then molding the entire upper part of the substrate with resin.

### BRIEF DESCRIPTION OF THE DRAWINGS

The above and other objects, features and other advantages of the present invention will be more clearly understood from the following detailed description taken in conjunction with the accompanying drawings, in which:

1. FIG. 1 is a sectional view of an RF module of the prior art;

2. FIG. 2 is a sectional view illustrating a first embodiment of the RF module according to the present invention;

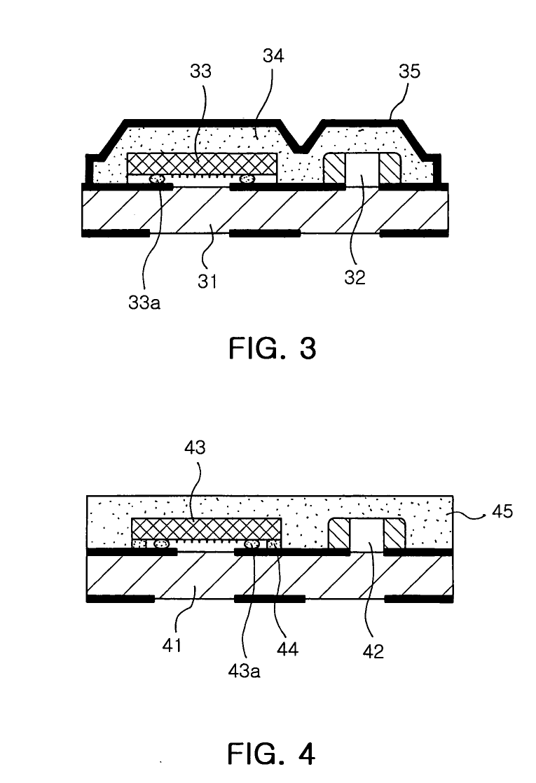

3. FIG. 3 is a sectional view illustrating a second embodiment of the RF module according to the present invention;

4. FIG. 4 is a sectional view illustrating a third embodiment of the RF module according to the present invention;

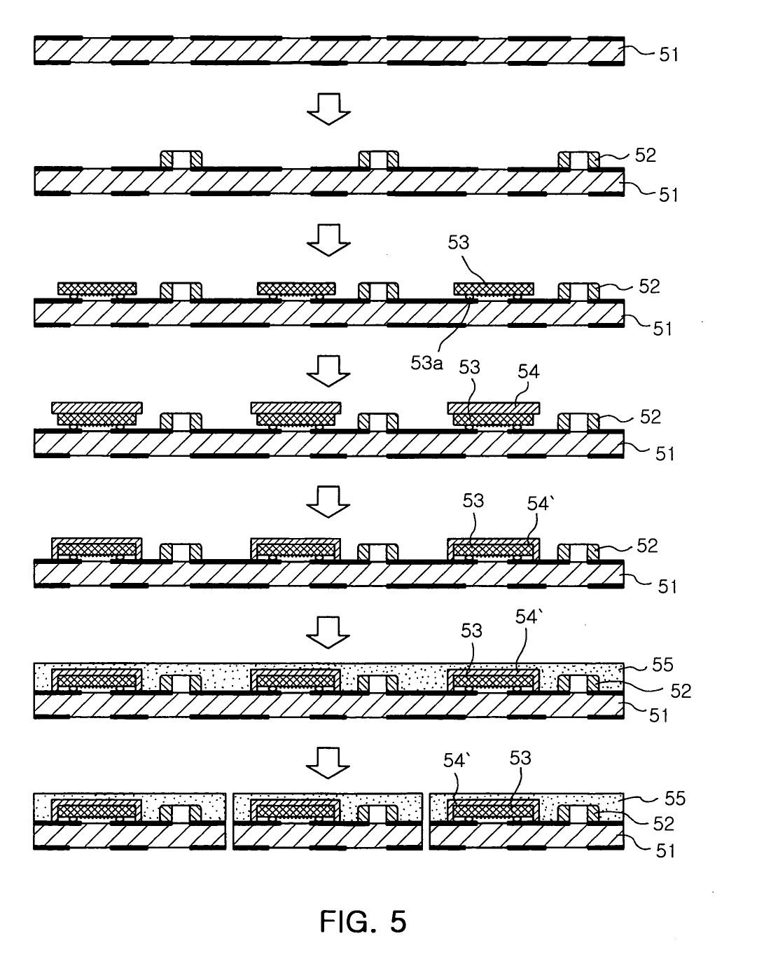

5. FIG. 5 is a flow chart illustrating a fabrication method of the first embodiment of the RF module according to the present invention;

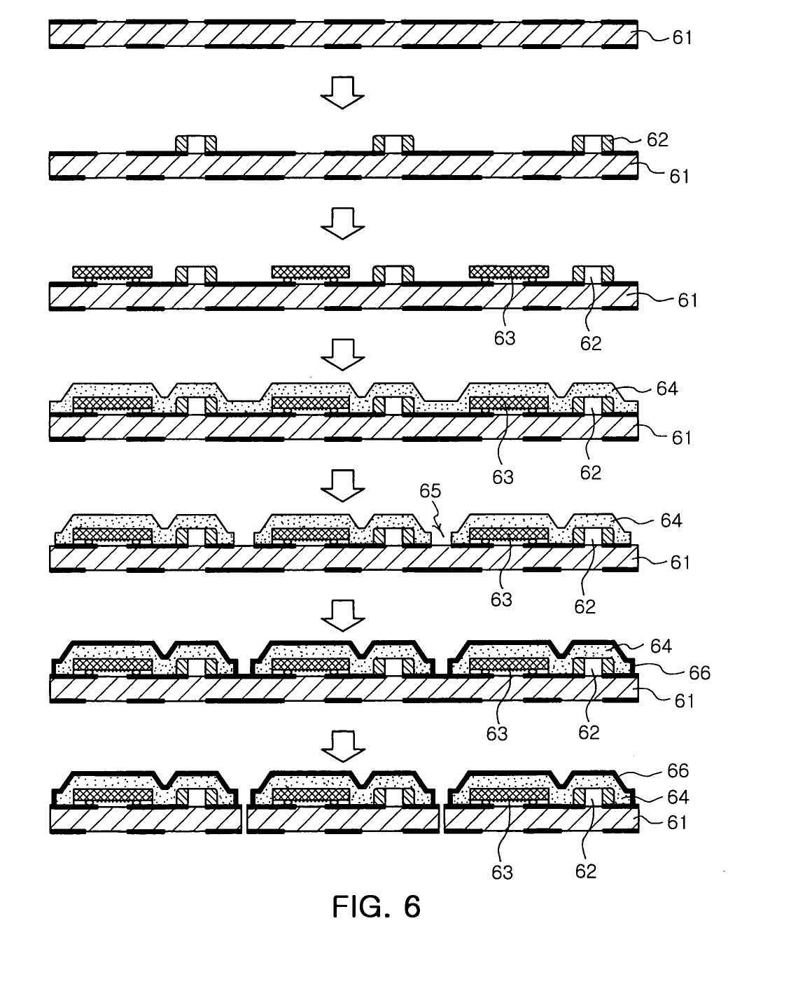

6. FIG. 6 is a flow chart illustrating a fabrication method of the second embodiment of the RF module according to the present invention; and

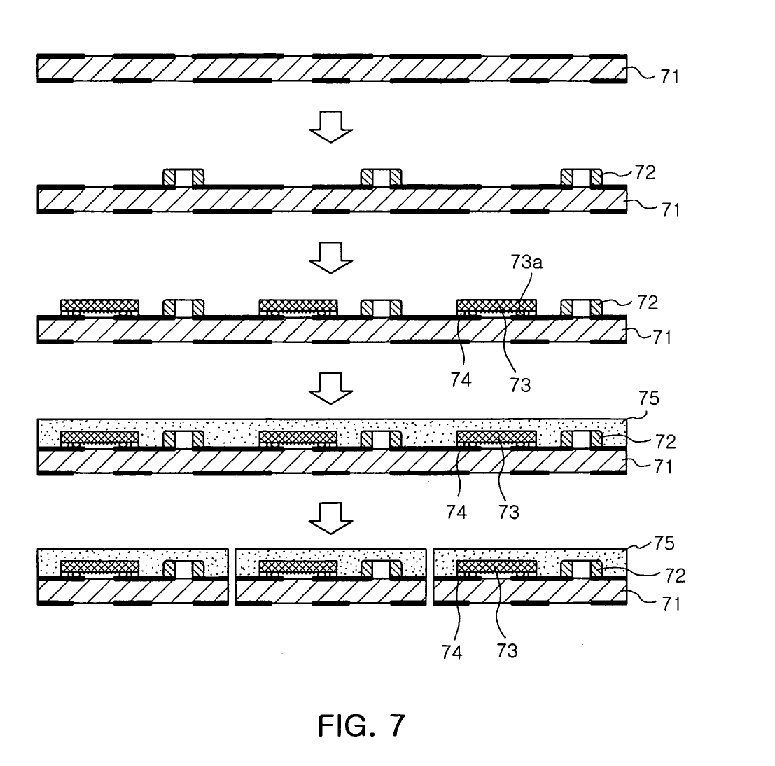

7. FIG. 7 is a flow chart illustrating the fabrication method of the third embodiment of the RF module according to the present invention.

### DETAILED DESCRIPTION OF THE PREFERRED EMBODIMENT

Preferred embodiments of the present invention will now be described in detail with reference to the accompanying drawings.

According to the present invention, a SAW component in a bare chip and other chip components are mounted on a substrate, and then the SAW component and other chip components are packaged simultaneously to eliminate the ceramic substrate of the prior art, thereby accommodating size reduction. This process is realized in the following three embodiments, varying in accordance with the package structure and methods thereof.

FIG. 2 is a sectional perspective view illustrating a first embodiment of the RF module according to the present invention. With reference to FIG. 2, the RF module of the present invention includes: a substrate 21 having component-connecting patterns formed thereon; a chip component 22, other than a SAW element, as a part of an RF circuit bonded to the substrate; a SAW component 23 flip-bonded to the substrate 21 in a bare chip; a thermosetting film 24 sealing the SAW chip 23; and molding resin 25 formed on the entire top part of the SAW component 23, the substrate 21, and the chip component 22.

The substrate 21 above includes a ceramic substrate such as HTCC and LTCC, or a PCB substrate. Also, the chip component 22 includes a Material Lamination Ceramic Capacitor (MLCC), a chip inductor, a chip resistance, and a chip switch.

Only a single chip component 22 and a SAW component 23 are shown in the diagram but there is no limit as to how many are used; there can be two or more, depending on the RF circuit or functions required.

The thermosetting film 24 includes a polyimide film and an epoxy film; molding resin 25 may be formed of one selected from a group including Epoxy Molding Compound (EMC), Epoxy Sheet Molding (ESM), Poly Phenylene Oxide (PPO) and a silicon film.

In the first embodiment, the thermosetting film 24 and molding resin 25 are used as packaging means.

When a SAW component 23 is directly mounted on a substrate 21 as described above, the ceramic substrate as shown in FIG. 1 can be eliminated to reduce the size. Moreover, sealing the SAW component 23 with the thermosetting film 24 allows stable operation of the SAW component 23.

The fabrication of an RF module according to a first embodiment of the present invention is conducted in a process as illustrated in FIG. 5.

As shown in FIG. 5, a plurality of chip components 52 are solder-bonded via SMT technique to the substrate 51 on which have the connecting patterns designed for an RF module are formed repeatedly in a matrix.

Thereafter, SAW components 53 in a bare chip are flip-bonded to the substrate 51. The flip-bonding can be done by two methods; one is forming a (Au) stud bump on each SAW chip 53 in a bare chip and performing a supersonic bonding; and the other is forming a solder bump on the substrate 51 and performing a heat fusion bonding. After either method, the thermosetting film is punched and coated only on the SAW components 53 mounted on the substrate 51, and then pressed to form a laminated film layer 54′.

In this film laminating process, the important factors are the material of the thermosetting film, temperature, time, and vacuum. For example, when a polyimide film is used as the thermosetting film 54, an optimal laminating result can be obtained under the condition in which the elasticity of the material being pressed is 0.2˜1 MPa, a temperature range is 170 to 220° C., processing time is 30 seconds to 2 minutes, and a vacuum is 0.5˜1.5 hpa. Of the numerous components mounted on the substrate 51 by the laminating process described above, only the SAW components 53 are sealed by the laminated film layer 54′. As a result, the SAW electrodes formed on the SAW components 53 are protected. Next, on top of the substrate 51, the resin is molded thicker than the thickness of the chip components 52 and the SAW components 53 to form a molding layer 55. The formation of the molding layer 55 can adopt any of the methods including transfer molding using EMC, molding by heat pressing epoxy sheet, extracting liquid type of molding material to be applied with heat treatment, and injection molding. Lastly, the molded substrate 51 is diced to form a plurality of RF modules.

According to the above described process of the present invention, the steps of forming the ceramic substrate and metal-plating of the prior art can be omitted, thereby simplifying the fabrication process.

FIG. 3 is a sectional perspective view illustrating a second embodiment of an RF module according to the present invention. With reference to FIG. 3, an RF module includes: a substrate 31 with component-connecting patterns formed thereon; a chip component 32 other than the SAW component bonded to the substrate 31; a SAW component 33 in a bare chip disposed on the substrate 31 in a flip-bonding structure; a thermosetting film 34 laminated on the substrate 31, the chip component 32, and the SAW component 32; and a metal-plated layer 35 formed on the top of the thermosetting film 34. In the above structure, the same types of substrate 31, chip component, and thermosetting film 34, as in the first embodiment, are used.

Since the parts, where the substrate 31 comes into contact with the metal-plated layer 35, are connected through the substrate to a ground terminal (not shown) located in the lower portion of the substrate 31, and a metal layer may be formed in advance on corresponding areas of the substrate 31 where the metal-plated layer 35 is to be formed, such that the metal-plated layer 35 can be attached to the substrate 31 more cohesively.

As in the first embodiment described above, one or more chip components 32 and SAW components 33 can be used.

In this second embodiment, a thermosetting film 34 and a metal-plated layer are used as packaging means.

In this second embodiment of the RF module of the present invention, a thermosetting film rather than molding resin 25 is laminated on the chip component 32 and the SAW component 33, thereby protecting the connecting patterns and the chip component 32 on the substrate 31, and sealing the SAW component 33, at the same time. In addition, metal-plated layer 35 can be formed on the top of the thermosetting film 34 to prevent moisture permeation, and moreover, by connecting this metal-plated layer 35 to the ground terminal of the substrate 31, a shielding effect of the electromagnetic field can be expected. Therefore, the fabrication process of this second embodiment can be even more simplified than that of the first embodiment.

FIG. 6 illustrates a stepwise fabrication method of an RF module of a second embodiment. The fabrication method of the second embodiment will now be explained below with reference to FIG. 6. To begin with, a plurality of chip components 62 is mounted simultaneously via SMT technique on the substrate where connecting patterns of a designed circuit are formed in a plurality of lines on the substrate 61.

Thereafter, a plurality of SAW components 63 are mounted on the substrate 61 by a flip-bonding. Next, a thermosetting film 64 is coated on the substrate 61, the chip component 62, and the SAW component 63, and then attached tightly to the substrate through a laminating process.

When the above laminating step of the thermosetting film 64 is completed, the thermosetting film 64 is removed along the boundaries of the modules to form grooves 65 that partially expose the substrate 61. Thereafter, a metal-plated layer 66 is formed on the top of the substrate 61 and the thermosetting film 64. Finally, each module is separated by dicing process.

The grooves 65 are used in order for the metal-plated layer 66 to closely adhere to the substrate 61, thereby enhancing the reliability in preventing moisture permeation. Thus, the film 64 on the boundaries of the modules needs to be removed completely. In addition, near the above boundaries on the substrate 61, a metal layer or patterns connected to the ground terminals of the lower portion are formed to ground the metal-plated layer 66. The electromagnetic wave from outside is grounded along the metal-plated layer 66, thereby resulting in a blocking effect against the electromagnetic wave. One of the methods of forming the above metal-plated layer is forming a seed metal by sputter and then performing electrolysis plating thereon.

FIG. 4 is a sectional view illustrating a third embodiment of the RF module according to the present invention. Referring to the FIG. 4, the RF module of the present invention includes: a substrate 41 having connecting patterns that connect the components thereon; a chip component 42 other than a SAW element flip-bonded on the substrate 41; a SAW component 43 in a bare chip, disposed in a flip-bonding structure on the substrate 31; a metal wall formed along the peripheral edge of the SAW component 43, in a space between the SAW component 43 and the substrate 41, thereby sealing the SAW component 43; and molding resin 45 formed over the substrate 41, the chip component 42, and the SAW component 43.

As in the above described embodiments, the number of the chip component 42 and the SAW component 43 can be one or more. The specific examples of the substrate 41, the chip component 42 and molding resin 45, are as illustrated in the first embodiment.

In this third embodiment according to the present invention, the metal wall 44 and molding resin 45 are used as packaging means.

In the RF module according to this third embodiment, a metal wall 44 is formed in a rectangular shape, between the SAW component 43 in a bare chip and the substrate 41, sealing the patterned part of the SAW component 43. In this embodiment, a sealing structure of a SAW component 43 is formed without the laminating process. Therefore, the process is even more simplified than those in the first and the second embodiments.

The above fabrication process according to the third embodiment is illustrated in FIG. 7. Referring to FIG. 7, first, a substrate 71 with the connecting patterns as a part of the RF circuit formed repeatedly, is prepared, and a plurality of chip components 72 are mounted on the substrate 71 via SMT technique.

The next step includes mounting a plurality of SAW components 73 and forming the metal wall 74. The metal wall 74 is formed either on the SAW component 73, together with bump balls 73a or on the area where the SAW components 73 are to be mounted. Then, a plurality of SAW components 73 is flip-bonded on the substrate 71, forming the SAW component 73 with the metal wall 74.

The metal wall 74 above is in a rectangular shape and is bonded to the edge of the patterned surface, forming a sealing wall after the saw component is flip-bonded. The methods of forming the metal wall 74 include screen-printing solder, performing non-electrolytic plating, and performing deposition. The material of the metal wall 74 includes Au or alloys containing Au such as AuSn.

The above flip-bonding can be conducted by ultrasonic bonding or heat fusion bonding as in the first embodiment.

Thereafter, a sealing structure of the SAW component 73 is formed. Then, according to the above process, molding resin 75 is formed to protect the substrate 71, the chip component 72, and the SAW component 73. Finally, individual RF modules are formed by dicing. The forming method of molding resin 75 is identical with the one described in the first embodiment.

According to the description set forth above, in the present invention, the ceramic package of the SAW component is eliminated, resulting in reduction of thickness and dimensions, thereby reducing the overall size and the thickness of the RF modules. Furthermore, the manufacturing step of ceramic package is omitted, as the formation of both the SAW component package and the protection means for the circuits of the RF module are carried out in a single step. As a result, the fabrication process is simplified, resulting in a considerable cost-saving effect by eliminating the ceramic package that accounts for a large amount of the total costs.

While the present invention has been shown and described in connection with the preferred embodiments, it will be apparent to those skilled in the art that modifications and variations can be made without departing from the spirit and scope of the invention as defined by the appended claims.

What is claimed is:

1. A Radio Frequency (RF) module comprising:
a substrate having component-connecting patterns formed thereon;
at least one chip component as an element other than SAW, mounted on the substrate;
at least one SAW component in a bare chip, flip-bonded to the substrate; and
a package formed on the substrate to seal the SAW component and protect the connecting patterns and the chip component on the substrate.

2. The Radio Frequency (RF) module according to claim 1, wherein the package comprises:
a thermosetting film laminated on the SAW component; and
molding resin coated on the substrate, the chip component, and the SAW component.

3. The Radio Frequency (RF) module according to claim 1, wherein the package comprises:
a thermosetting film laminated on the substrate, the chip component, and the SAW component; and
a metal-plated layer formed on the top of the thermosetting film.

4. A Radio Frequency (RF) module according to claim 1, wherein the package comprises:
a metal wall disposed between the flip-bonded SAW component and the substrate, sealing the SAW component; and
molding resin coated on the substrate, the chip component, and the SAW component.

5. A fabrication method of Radio Frequency (RF) modules comprising steps of:
preparing a substrate having a plurality of connecting patterns formed repeatedly;
solder-bonding plural chip components on the substrate;
flip-bonding at least one SAW component in a bare chip on the substrate;
packaging a structure formed in the above steps to seal the SAW component and protect the connecting patterns and the chip component on the substrate; and
dicing the packaged substrate into a plurality of unit RF modules.

6. The fabrication method of an RF module according to claim 5, wherein the packaging step comprises:
coating and laminating a punched thermosetting film on the SAW component; and
molding the substrate, the chip component, and the SAW component with resin.

7. The fabrication method of an RF module component according to claim 5, wherein the packaging step comprises:
laminating a thermosetting film on the chip component and the SAW component;
removing the thermosetting film in part from the boundary between the unit modules on the substrate; and
metal-plating the top of the substrate and the thermosetting film.

8. The fabrication method of an RF module according to claim 5, wherein the step of flip-bonding the SAW component comprises:
forming a bump ball and a metal wall in a rectangular shape, on the SAW component or the substrate; and
flip-bonding the SAW component to bond the metal wall between the SAW component and the substrate.

9. The fabrication method of an RF module according to claim 8, wherein the packaging step comprises molding the substrate, the chip component and the SAW component with resin.
